(19) United States
(12) Patent Application Publication
(10) Pub. No.: US 2002/0154492 A1
(43) Pub. Date: Oct. 24, 2002

(54) Assembling structure of electronic device

(76) Inventors: Kai Hung Huang, Taoyuan Shien (TW); Yi Hwa Hsieh, Taoyuan Shien (TW); Kun-Feng Chen, Taoyuan Shien (TW)

Correspondence Address: Allen, Dyer, Doppelt, Milbrath & Gilchrist, P.A., 1401 Citrus Center, 255 South Orange Avenue, Post Office Box 3791, Orlando, FL, 32802-3791, US

(21) Appl. No.: 09/876,315

(22) Filed: Jun. 7, 2001

(30) Foreign Application Priority Data
Apr. 24, 2001 (TW) 090206492

(51) Int. Cl. H05K 1/11

(52) U.S. Cl. 361/784

(57) ABSTRACT

An assembling structure of electronic devices for an electronic product is provided. The assembling structure includes a first circuit board, a second circuit board having higher thermal conductivity than the first circuit board and at least one high-power electronic device mounted thereon, and a connecting element for electrically coupling the first circuit board with the second circuit board.

### FIELD OF THE INVENTION

The present invention relates to an assembling structure of electronic devices, and more particularly, to an assembling structure of electronic devices for enhancing heat dissipation.

### BACKGROUND OF THE INVENTION

Typically, electronic devices are mounted and electrically connected to a printed circuit board in accordance with a surface mounting technology. Such circuit board is produced by interconnecting copper foil with organic materials such as glass fiber reinforced epoxy, polyester, etc. For example, a DC to DC converter is assembled by configuring electronic devices such as capacitors, resistors, inductors, transformers, diodes, MOSFETs and bare dice. When the converter operates, these electronic devices generate energy in the form of heat. If the electronic device is unable to transfer enough heat to the ambient air, the elevated operating temperature might result in the failure of the electronic devices or the breakdown of the whole product. For low power electronic devices such as the capacitors or the resistors, the heat can be easily dissipated by natural convection. However, the heat generated from the higher power electronic devices could be dissipated by forced convection. The heat resistance of the natural convection or forced convection is dependent on the size of the heat transfer area, and thus an attached heat sink is usually required, which not only increases the cost but also occupies space.

The conventional circuit board, for example a glass fiber reinforced epoxy circuit board (FR-4 PCB), has a solder attaching failure and a tensile failure due to thermal stress. Such circuit board has also an advantage of heat generation. A specifically designed heat sink is required and such heat sink is difficult to attach to the circuit board, which increases the assembling cost. In addition, such circuit board attached to a heat sink still has poor heat dissipation. The plastic molded electronic devices, for example SO-08 and SOT-23, mounted on the circuit board are not easily dissipated, which reduces the operation life.

In order to solve the problem described above, a highly thermal conductive substrate is developed. Such substrate includes metal substrates and ceramic substrates. FIG. 1 is a schematically perspective view illustrating the structure of a metal substrate according to the prior art. The structure of the metal substrate 10 includes a base layer 11, a dielectric layer 12 and a circuit layer 13 in order from bottom to top. The base layer is usually made of aluminum, copper or other metals and has a thickness of about 0.5 to 3.2 mm. The circuit board 13 is a copper foil having a thickness of about several hundred micrometer. The ceramic substrate is principally made of aluminum oxide (Al₂O₃) or beryllium oxide (BeO), which is known to a person skilled in the art. Since the highly thermal conductive substrate could overcome the above-mentioned drawbacks in the prior art, it still has the disadvantages as follows:

(1) the highly thermal conductive substrate is about ten times cost of the traditional FR-4 PCB; and

(2) the highly thermal conductive substrate has very good conductivity such that the high-power electronic devices deliver more heat to the low-power electronic devices and thus adversely affects their function.

Therefore, the present invention provides an assembling structure of electronic devices for enhancing heat dissipation so as to overcome the problems described above.

### SUMMARY OF THE INVENTION

The object of the present invention is to provide an assembling structure of electronic devices for enhancing heat dissipation, improving the layout flexibility and reducing the cost of assembly.

In accordance with one aspect of the present invention, there is provided an assembling structure adapted to an electronic product. The assembling structure includes a first circuit board, a second circuit board and a connecting element. The second circuit board has higher thermal conductivity than the first circuit board and at least one high-power electronic device mounted thereon. The connecting element is suitable for electrically coupling the first circuit board with the second circuit board.

Preferably, the electronic product is a DC to DC converter. The first circuit board is one selected from a group consisting of a copper clad laminate (CCL) substrate circuit board, a glass fiber reinforced epoxy substrate board and a thermoplastic substrate board. The second circuit board is a highly thermal conductive substrate board. Preferably, the highly thermal conductive substrate circuit board is one of a clad metal substrate board and a ceramic substrate board. The high-power electronic device is one selected from a group consisting of a transformer, a MOSFET (metal-oxide-semiconductor field effect transistor), a bare die, a diode, a winding and an inductor.

Preferably, the connecting element is made of a material having high conductivity, which is one selected from a group consisting of copper, gold and silver.

Preferably, the second circuit board is disposed above the second circuit board. The connecting element is in a shape of a bar for supporting the second circuit board.

Preferably, the second circuit board is disposed beside the second circuit board. The connecting element is in a shape of a wire, a strip or a sheet.

Preferably, the second circuit further includes a heat sink attached thereto.

In accordance with another aspect of the present invention, there is provided an assembling structure adapted to an electronic product. The assembling structure includes a first circuit board selected from a group consisting of a copper clad laminate (CCL) substrate circuit board, a glass fiber reinforced epoxy substrate board and a thermoplastic substrate board, a second circuit board is a high thermal conductive substrate that selected from one of a clad metal substrate board and a ceramic substrate board and having at least one high-power electronic device mounted thereon, and a connecting element for electrically coupling the first circuit board with the second circuit board.

Preferably, electronic product is a DC to DC converter.

Preferably, the high-power electronic device is one selected from a group consisting of a transformer, a MOSFET, a bare die, a diode, a winding and an inductor.

Preferably, the connecting element is made of a material having high electronic and thermal conductivity, for example copper, gold and silver.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view of a clad metal substrate board according to prior art;

FIG. 2(a) is a schematically perspective view illustrating the assembling structure according to a first embodiment of the present invention;

FIG. 2(b) is a front sectional view of FIG. 2(a);

FIG. 3(a) is a schematically perspective view illustrating the assembling structure according to a second embodiment of the present invention; and

FIG. 3(b) is a front sectional view of FIG. 3(a).

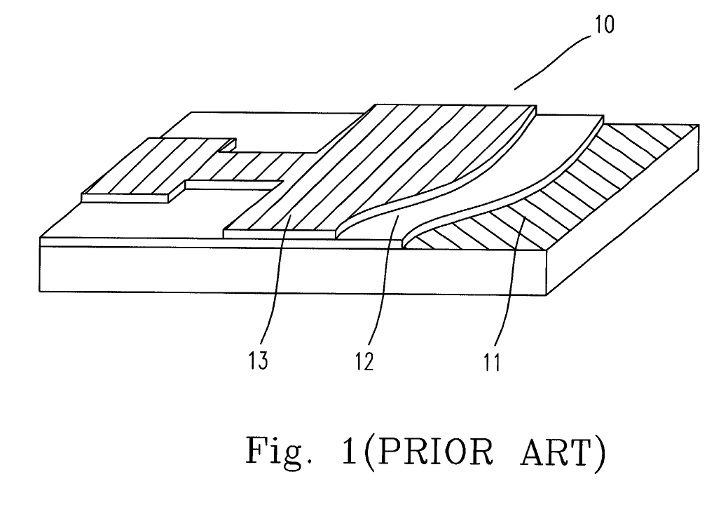

### DETAILED DESCRIPTION OF THE PREFERRED EMBODIMENT

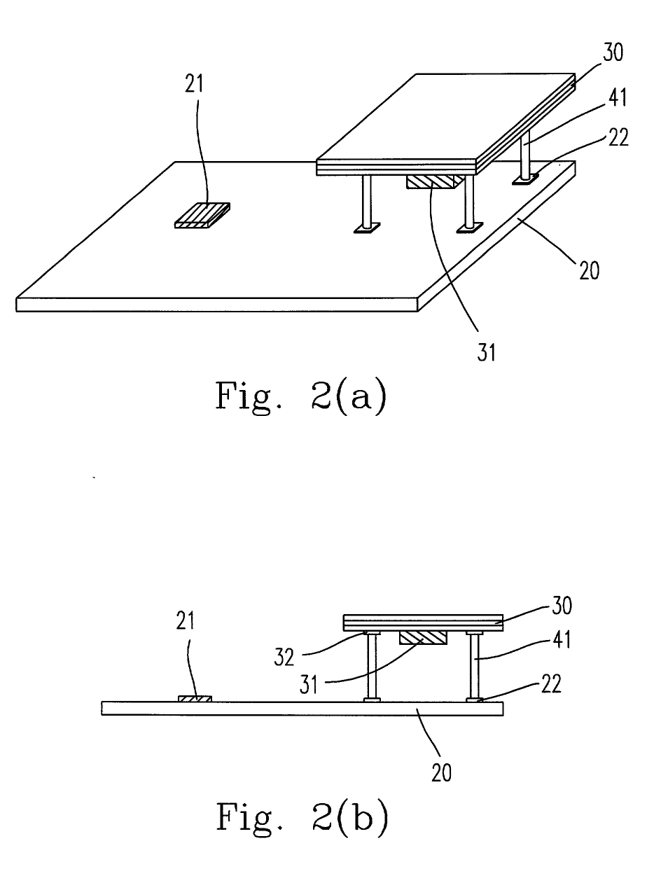

FIGS. 2(a) and 2(b) are schematically perspective view and sectional view of assembling structure according to the first embodiment of the present invention. The assembling structure includes a first circuit board 20, a second circuit board 30 and a connecting element 41. In order to preventing the heat dissipated by high-power electronic devices from noticeably affecting the other electronic devices and enhancing heat dissipation and layout flexibility, the present invention is designed based on two concepts. First, the second circuit board 30 is more thermally conductive than the first circuit board, and secondly a major portion of the high-power electronic devices are mounted on the second circuit board 30.

In this embodiment, the assembling structure according to the present invention is adapted to assemble an electronic product such as a DC to DC converter. Preferably, the first circuit board 20 is selected from but not limited to a traditional circuit board such as a copper clad laminate (CCL) substrate circuit board, a glass fiber reinforced epoxy substrate board and a thermoplastic substrate board. The second circuit board 30 is preferably a highly thermal conductive substrate board, for example a clad metal substrate board or a ceramic substrate board. A portion of high-power electronic devices 31 of the DC to DC converter are mounted on the second circuit board 30. These high-power electronic devices include but not limited to transformers, MOSFETs, bare dice, diodes, windings and inductors, which generate much heat while operating. Certainly, dependent on the demand of circuit configuration and assembling cost, the first circuit board 20 can retain some high-power electronic devices (not shown) and the second circuit board 30 can also have some low-power electronic devices (not shown).

Referring to FIGS. 2(a) and 2(b), the second circuit board 30 is disposed above the first circuit board 20. The bars 41 are employed for electrically coupling the first circuit board 20 with the second circuit board 30 and supporting the second circuit board 30. The bar 41 is made of a material having high electronic and thermal conductivity, for example copper, gold and silver.

The assembling structure according to the present invention allows most of the heat generated from the high-power electronic devices 31 dissipates through the second circuit board 30 to the ambient air. 13. The second circuit 30 could further have a heat sink attached onto a surface thereof for facilitating heat dissipation. Since the medium between the first circuit board 20 and the second circuit board 30 is principally air, the heat generated from the high-power electronic devices 31 has little effect on the electronic devices 21 of the first circuit board 20.

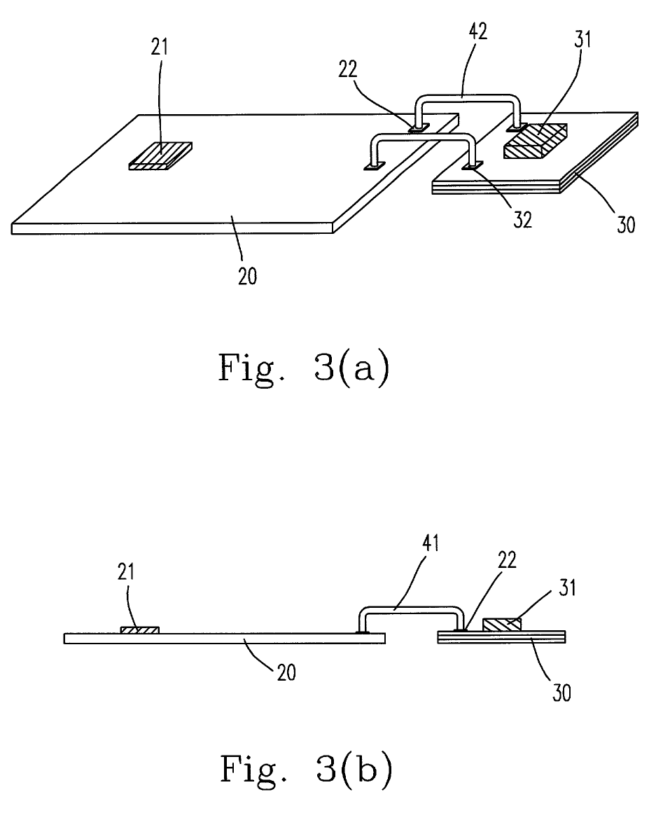

FIGS. 3(a) and 3(b) are schematically perspective view and sectional view of assembling structure according to the second embodiment of the present invention. The structure and the operation principle are the same as those in FIGS. 2(a) and 2(b) except that the second circuit board 30 is disposed beside the first circuit board 30 and the connecting element between the first circuit board 20 and the second circuit board 30 are in a shape of a wire, a strip or a sheet.

As will be apparent from the above description according to the present invention, the assembling structure of the electronic devices has the following advantages:

(a) since most high-power electronic devices are disposed on the second circuit board 30, i.e. a highly thermal conductive substrate, the heat dissipation is largely enhanced;

(b) the size of the second circuit board 30 which is required in the present invention could be much smaller than the size of completely employing the highly thermal conductive substrate;

(c) the relative disposition between the first circuit board 20 and the second circuit board 30 is optional, thus the layout flexibility is improved; and

(d) the assembling structure of the present invention could further include a heat sink attached on the second circuit board 30 for overcoming the drawback occurred in the traditional FR-4 PCB and enhancing heat dissipation.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An assembling structure of electronic devices for an electronic product, comprising:
a first circuit board;
a second circuit board having higher thermal conductivity than said first circuit board and at least one high-power electronic device mounted thereon; and
a connecting element for electrically coupling said first circuit board with said second circuit board.

2. The assembling structure according to claim 1, wherein said electronic product is a DC to DC converter.

3. The assembling structure according to claim 1, wherein said first circuit board is one selected from a group consisting of a copper clad laminate (CCL) substrate circuit board, a glass fiber reinforced epoxy substrate board and a thermoplastic substrate board.

4. The assembling structure according to claim 1, wherein said second circuit board is a highly thermal conductive substrate board.

5. The assembling structure according to claim 4, wherein said highly thermal conductive substrate circuit board is one of a clad metal substrate board and a ceramic substrate board.

6. The assembling structure according to claim 4, wherein said high-power electronic device is one selected from a group consisting of a transformer, a MOSFET (metal-oxide-semiconductor field effect transistor), a bare die, a diode, a winding and an inductor.

7. The assembling structure according to claim 1, wherein said connecting element is made of a material having high electronic and thermal conductivity.

8. The assembling structure according to claim 7, wherein said material is one selected from a group consisting of copper, gold and silver.

9. The assembling structure according to claim 1, wherein said second circuit board is disposed above said second circuit board.

10. The assembling structure according to claim 9, wherein said connecting element is in a shape of a bar for supporting said second circuit board.

11. The assembling structure according to claim 1, wherein said second circuit board is disposed beside said second circuit board.

12. The assembling structure according to claim 11, wherein said connecting element is in a shape selected from a group consisting of a wire, a strip and a sheet.

13. The assembling structure according to claim 1, wherein said second circuit further includes a heat sink attached thereto.

14. An assembling structure of electronic devices for an electronic product, comprising:
a first circuit board selected from a group consisting of a copper clad laminate (CCL) substrate circuit board, a glass fiber reinforced epoxy substrate board and a thermoplastic substrate board;
a second circuit board selected from one of a clad metal substrate board and a ceramic substrate board and having at least one high-power electronic device mounted thereon; and
a connecting element for electrically coupling said first circuit board with said second circuit board.

15. The assembling structure according to claim 14, wherein said electronic product is a DC to DC converter.

16. The assembling structure according to claim 15, wherein said high-power electronic device is one selected from a group consisting of a transformer, a MOSFET (metal-oxide-semiconductor field effect transistor), a bare die, a diode, a winding and an inductor.

17. The assembling structure according to claim 14, wherein said connecting element is made of a material having high electronic and thermal conductivity.

18. The assembling structure according to claim 17, wherein said material is one selected from a group consisting of copper, gold and silver.
